(19) United States
(12) Patent Application Publication
(10) Pub. No.: US 2026/0169371 A1
(43) Pub. Date: Jun. 18, 2026

(54) OPTIMIZATION OF PHOTOMASK PATTERNS

(71) Applicant: GDM Holding LLC, Mountain View, CA (US)

(72) Inventor: Cyrus Behroozi, Menlo Park, CA (US)

(21) Appl. No.: 18/984,377

(22) Filed: Dec. 17, 2024

(51) Int. Cl. G03F 1/36; G03F 1/70

(52) U.S. Cl. CPC G03F 1/36; G03F 1/70

(57) ABSTRACT

The technology involves exploration of design space for photomask patterns that is unconstrained by manufacturability constraints while still yielding photomask patterns that satisfy those manufacturability constraints. A method includes determining a first photomask pattern corresponding to a target physical design of a semiconductor device. Determining the first photomask pattern is unconstrained by a minimum feature size. Features of the first photomask pattern that are smaller than the minimum feature size are removed to generate a second photomask pattern. A gradient mask is determined based on the second photomask pattern, by setting values of a first set of pixels of a gradient pattern corresponding to boundary pixels of the second photomask pattern to one, and setting values of a second set of pixels of the gradient pattern to zero. A third photomask pattern is determined based on the gradient mask pattern and the second photomask pattern.

### BACKGROUND

In semiconductor manufacturing, photomasks may be used to form patterns on semiconductor wafers (also referred to herein as “wafers”) according to patterns of the photomasks (also referred to herein as “photomask patterns”). A photomask pattern is based on a physical design of a semiconductor device (also referred to herein as “target physical design”) to be formed on a wafer. A pattern formed on a wafer based on a photomask pattern may be distorted relative to the target physical design due to optical diffraction, resist diffusion, and/or other physical effects associated with forming the pattern on the wafer. For example, target physical designs may include features having sharp corners that are more susceptible to distortion from optical diffraction or resist diffusion. To mitigate or compensate for such distortion, a photomask pattern may be modified so that a pattern formed on the semiconductor wafer is more similar to (e.g., better approximates) a target physical design.

Inverse lithography (ILT) includes modeling lithography processes to determine and/or optimize photomask patterns to mitigate or compensate for distortion in patterns formed in wafers using those photomask patterns. However, these previous approaches require that photomask patterns always satisfy manufacturability constraints including, but not limited to, minimum feature sizes. That is, a feature of a photomask pattern must be at least a minimum size. Exploration of design space for photomask patterns by previous approaches is constrained by these manufacturability constraints.

### SUMMARY

The technology provides exploration of design space for photomask patterns that is, at least partially, unconstrained by manufacturability constraints (e.g., minimum feature sizes) while still yielding photomask patterns that satisfy those manufacturability constraints.

Semiconductor manufacturing processes or systems, such as laser mask writers and electron beam mask writers, may have a maximum resolution. A maximum resolution for a particular semiconductor manufacturing process or system may correspond to a minimum feature for that semiconductor manufacturing process or system. If a feature of a photomask pattern has less than a minimum feature size, then that feature may not show up on the resulting photomask, may flake off the resulting photomask, and/or may cause contamination elsewhere on the resulting photomask. Thus, there is a need to ensure that photomask patterns conform to manufacturability constraints, such as a minimum feature size.

The disclosed technology may include an optimization of a photomask pattern that is unrestricted by manufacturability constraints. This optimization can include a gradient descent towards the target physical design to be fabricated. However, this may generate sub-resolution assist features (SRAFs) that are not in the target physical design. SRAFs may sharpen corners in a pattern formed on a semiconductor wafer, thereby improving correspondence between a target physical design and formed on a semiconductor wafer. Because this optimization is unrestricted by manufacturability constraints associated with particular semiconductor manufacturing processes or systems, the photomask pattern generated from this optimization (also referred to herein as “intermediate photomask pattern”) may not be manufacturable by those particular semiconductor manufacturing processes or systems. For example, the intermediate photomask pattern may include features that are smaller than a minimum feature size of a semiconductor manufacturing process or system with which the intermediate photomask pattern would be used.

According to one aspect of the technology, a method includes determining, by one or more processors, a first photomask pattern corresponding to a target physical design of a semiconductor device, wherein determining the first photomask pattern is unconstrained by a minimum feature size; removing, by one or more processors, one or more features of the first photomask pattern that are smaller than the minimum feature size to generate a second photomask pattern; determining, by one or more processors based on the second photomask pattern, a gradient mask pattern, by: setting values of a first set of pixels of a gradient pattern including one or more pixels corresponding to boundary pixels of the second photomask pattern to one; and setting values of a second set of pixels of the gradient pattern to zero; and determining, by one or more processors based on the gradient mask pattern and the second photomask pattern, a third photomask pattern.

In an example, the first set of pixels may further include. one or more pixels of the gradient pattern corresponding to one or more pixels of the second photomask pattern adjacent to the boundary pixels.

Alternatively or additionally to the above, the second set of pixels may include all pixels of the gradient pattern other than the first set of pixels.

Alternatively or additionally to the above, determining the third photomask pattern may include purposefully distorting the second photomask pattern relative to the target physical design. Here, purposefully distorting the second photomask pattern may include compensating for at least one of optical diffraction or resist diffusion associated with forming a pattern on a wafer using the third photomask pattern.

Alternatively or additionally to the above, determining the gradient mask pattern may further include identifying the boundary pixels.

Alternatively or additionally to the above, determining the third photomask pattern may not introduce an island or a void.

Alternatively or additionally to the above, the method may further include causing the semiconductor device to be fabricated based on the third photomask pattern.

According to another aspect of the technology, a system is provided that comprises memory configured to store a target physical design of a semiconductor device to be fabricated and one or more processors operatively coupled to the memory. The one or more processors are configured to: determine a first photomask pattern corresponding to the target physical design, wherein the determination of the first photomask pattern is unconstrained by a minimum feature size; remove one or more features of the first photomask pattern that are smaller than the minimum feature size to generate a second photomask pattern; determine, based on the second photomask pattern, a gradient mask pattern, by being configured to: set values of a first set of pixels of a gradient pattern including one or more pixels corresponding to boundary pixels of the second photomask pattern to one; and set values of a second set of pixels of the gradient pattern to zero; and determine, based on the gradient mask pattern and the second photomask pattern, a third photomask pattern.

In an example, the first set of pixels may further include. one or more pixels of the gradient pattern corresponding to one or more pixels of the second photomask pattern adjacent to the boundary pixels.

Alternatively or additionally to the above, the second set of pixels may include all pixels of the gradient pattern other than the first set of pixels.

Alternatively or additionally to the above, the one or more processors may be further configured to purposefully distort the second photomask pattern relative to the target physical design to determine the third photomask design. Here, the one or more processors may further be configured to purposefully distort the second photomask pattern by being configured to compensate for at least one of optical diffraction or resist diffusion associated with forming a pattern on a wafer using the third photomask pattern.

Alternatively or additionally to the above, the one or more processors may be further configured to identify the boundary pixels.

Alternatively or additionally to the above, wherein the one or more processors may be further configured to determine the third photomask pattern without introducing an island or a void.

Alternatively or additionally to the above, the one or more processors may be further configured to cause the semiconductor device to be fabricated based on the third photomask pattern.

### BRIEF DESCRIPTION OF THE DRAWINGS

FIG. 1 illustrates an integrated circuit design flow in accordance with aspects of the technology.

FIG. 2 illustrates an example system that may be employed with aspects of the technology.

FIGS. 3A-D illustrate an example optimization of a photomask pattern in accordance with aspects of the technology.

FIG. 4 illustrates an example method in accordance with aspects of the technology.

### DETAILED DESCRIPTION

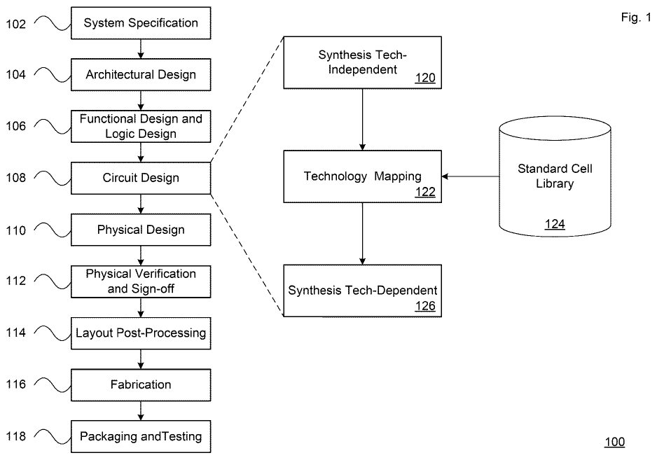

FIG. 1 illustrates an exemplary integrated circuit design flow 100 for use with aspects of the technology, including generating a circuit design and/or fabricating an integrated circuit that incorporates optimization of spline-based representations of interconnects. As shown, the design flow may include preparing a system specification at block 102, such as to identify system-level requirements for the integrated circuit. The system specification is intended to capture the overall goal of the desired integrated circuit. This may include determining the device's cost, performance, general architecture, how off-chip communication will be conducted, etc. The process flow may also include performing architectural design at block 104. At this stage, the design's architecture and its layout are determined by design engineers. This can include integration of memory management, analog and/or mixed-signal components, on-device and external communication, any power constraints, choice of process technology and/or layer stacks, etc.

The process flow continues with performing functional design and logic design at block 106, and performing circuit design at block 108. Functional design may include refinement of the design's specification to achieve the functional behavior of the desired system. Logic design involves adding the design's structure to a behavioral representation of the desired design. Here, considerations include logic minimization, performance enhancement, as well as testability. This stage may consider problems associated with test vector generation, error detection and correction, and the like. By way of example, the functional design and logic design may include generating a behavioral model description (e.g., using HDL) and floor-planning. During circuit design, logic blocks are replaced by corresponding electronic circuits, which may include devices such as resistors, capacitors, and/or transistors. At this stage, circuit simulation may be performed in order to verify timing behavior and other constraints of the system. A Spice tool or other program may be used for circuit simulation.

Once the circuit design is complete, physical design may be performed at block 110 (e.g., component and wiring placement and routing), followed by physical verification and sign-off at block 112 (e.g., to obtain GDSII information with shapes to form the masks used to create the layers for fabricating the integrated circuit). During physical design, the actual layout of the integrated circuit is performed. Here, all of the components are placed and interconnected using metal interconnections. During this stage, the system may perform optimization of curvilinear interconnects, alternatively or additionally to any other layout operations. A circuit design that is able to pass testing of a circuit simulator in the circuit design stage may be found to be faulty after it has been packaged, e.g., due to geometric design rule issues. Thus, physical design rules are followed to ensure correctness during chip fabrication. Errors may include short or open circuits, open channels, or other issues may result when physical design rules are not followed. During physical verification and sign-off, the system performs any verification steps that are required before chip manufacturing. This can include design rule checking and correction, timing simulation, electromagnetic simulation, etc.

Layout post-processing occurs at block 114, then fabrication at block 116, and the packaging and testing at block 118. At block 114, the layout post-processing may include geometry processing before actual manufacturing, e.g., any dummy fill insertion, correction for optical proximity, mask optimization, etc. Fabrication comprises semiconductor manufacturing, which includes stages such as lithography patterning (masking), baking or annealing, etching, etc. Then the raw die of the chip is inserted into a package and I/O pins are connected to the package at block 118. Testing of the chip also occurs at this stage.

As shown, in the circuit design phase of block 108, the process may involve technology-independent synthesis at block 120. This step involves transferring the circuit definitions, such as register-transfer-level (RTL) descriptions, into generic data structures such as And-inverter graph (AIG), and optimizing the circuit in terms of nodes and levels. At block 122, technology mapping is performed based on information from a standard cell library 124. This step involves maps the generic optimized AIG descriptions into real, manufacturable standard cells included in the standard cell library. From this, technology-dependent synthesis is then performed at block 126. This step further optimizes the circuit defined in the gate-level netlist in terms of power, performance and area, using standard-cell-based definitions from block 122.

### Example Integrated Circuit Development System

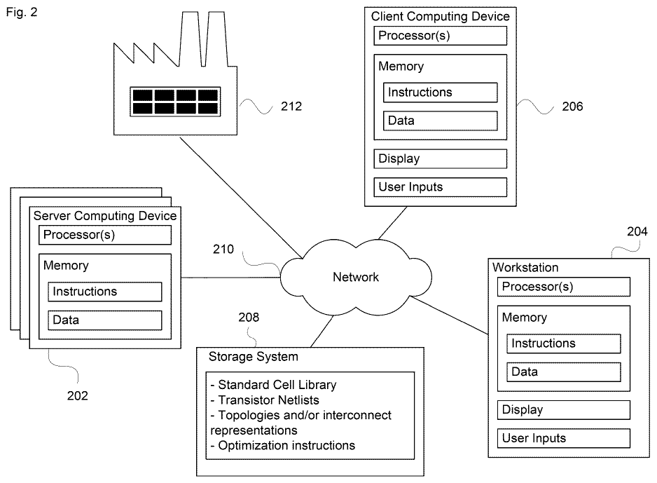

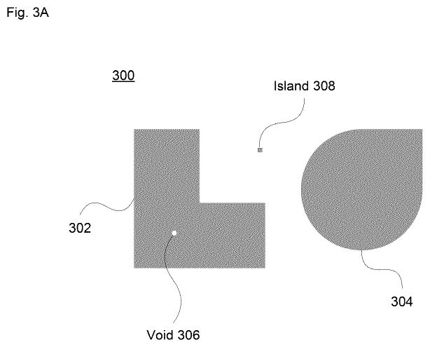

One example of a system for performing circuit design is shown in FIG. 2. In particular, FIG. 2 is a functional diagram, of an example system 200 that includes a plurality of computing devices 202, 204, 206 and a storage system 208 connected via a network 210. System 200 may also include a fabrication facility 212 that is configured to produce integrated circuits designed according to the processes described herein. As shown in FIG. 2, each of computing devices 202, 204 and 206 may include one or more processors, memory, data and instructions.

By way of example, the one or more processors may be any conventional processors, such as commercially available central processing units (CPUs), graphical processing units (GPUs) or tensor processing units (TPUs). Alternatively, the one or more processors may include a dedicated device such as an ASIC or other hardware-based processor. As shown in FIG. 2, the memory for each computing device stores information accessible by the one or more processors, including instructions and data that may be executed or otherwise used by the processor(s). The memory may be of any type capable of storing information accessible by the processor, including a computing device or computer-readable medium, or other medium that stores data that may be read with the aid of an electronic device, such as a hard-drive, memory card, ROM, RAM, DVD or other optical disks, as well as other write-capable and read-only memories. Systems and methods may include different combinations of the foregoing, whereby different portions of the instructions and data are stored on different types of media.

Moreover, reference to “one or more processors” herein includes situations where a set of processors may be configured to perform one or more operations. Any combination of such a set of processors may perform individual operations or a group of operations. This may include two or more CPUs, GPUs or TPUs (or other hardware-based processors) or any combination thereof. It may also include situations where the processors have multiple processing cores. Therefore, reference to “one or more processors” does not require that all processors (or cores) in the set must each perform all of the operations. Rather, unless expressly stated, any one of the one or more processors (or cores) may perform different operations when a set of operations is indicated, and different processors (or cores) may perform specific operations, either sequentially or in parallel.

The instructions may be any set of instructions to be executed directly (such as machine code) or indirectly (such as scripts) by the processor. For example, the instructions may be stored as computing device code on the computing device-readable medium. In that regard, the terms “instructions” and “programs” may be used interchangeably herein. The instructions may be stored in object code format for direct processing by the processor, or in any other computing device language including scripts or collections of independent source code modules that are interpreted on demand or compiled in advance. The instructions may include a method for optimization of spline-based routing of interconnects as discussed herein.

The data may be retrieved, stored or modified by the processor in accordance with the instructions. For instance, although the claimed subject matter is not limited by any particular data structure, the data may be stored in computing device registers, in a relational database as a table having a plurality of different fields and records, XML documents or flat files, HDL information, GDSII information, etc. The data may also be formatted in any computing device-readable format.

The computing devices may include all of the components normally used in connection with a computing device such as the processor and memory described above as well as a user interface having one or more user inputs (e.g., one or more of a button, mouse, keyboard, touch screen, gesture input and/or microphone), various electronic displays (e.g., a monitor having a screen or any other electrical device that is operable to display information), and speakers. The computing devices may also include a communication system having one or more wired or wireless connections to facilitate communication with other computing devices of system 200 and/or the fabrication facility 212.

The various computing devices may communicate directly or indirectly via one or more networks, such as network 210. The network 210 and any intervening nodes may include various configurations and protocols including short range communication protocols such as Bluetooth™, Bluetooth LE™, the Internet, World Wide Web, intranets, virtual private networks, wide area networks, local networks, private networks using communication protocols proprietary to one or more companies, Ethernet, WiFi and HTTP, and various combinations of the foregoing. Such communication may be facilitated by any device capable of transmitting data to and from other computing devices, such as modems and wireless interfaces.

In one example, computing device 202 may include one or more server computing devices having a plurality of computing devices, e.g., a load balanced server farm or cloud computing architecture, which exchange information with different nodes of a network for the purpose of receiving, processing, and transmitting the data to and from other computing devices. For instance, computing device 202 may include one or more server computing devices that are capable of communicating with computing devices 204, 206 and the fabrication facility 212 via the network 210. In some examples, client computing device 204 may be an engineering workstation used by a developer to perform circuit design and/or other processes for integrated circuit design and fabrication. Client computing device 206 may also be used by a developer, for instance to prepare system requirements for the integrated circuit or manage the manufacturing process with the fabrication facility 212.

Storage system 208 can be of any type of computerized storage capable of storing information accessible by the server computing devices 202, 204 and/or 206, such as a hard-drive, memory card, ROM, RAM, DVD, CD-ROM, flash drive and/or tape drive. In addition, storage system 208 may include a distributed storage system where data is stored on a plurality of different storage devices which may be physically located at the same or different geographic locations. Storage system 208 may be connected to the computing devices via the network 210 as shown in FIG. 2, and/or may be directly connected to or incorporated into any of the computing devices.

Storage system 208 may store various types of information. For instance, the storage system 208 may store physical designs of semiconductors, photomask patterns, and/or other mask patterns associated with semiconductor fabrication processes or systems as well as instructions for performing optimizations and other processes described herein.

### Example Implementations

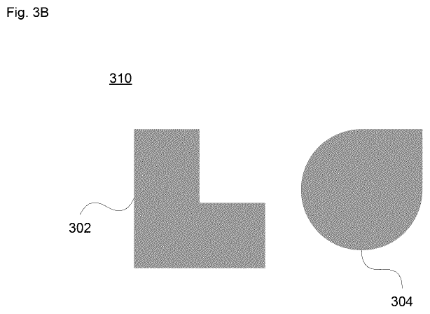

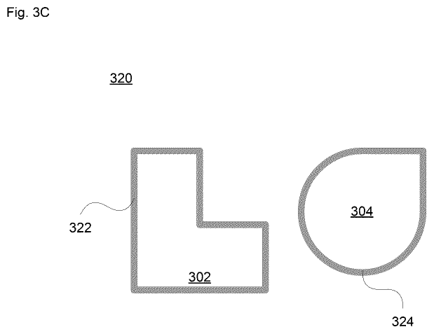

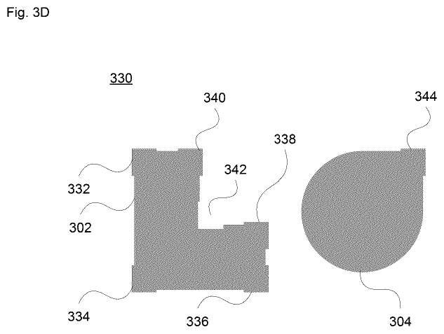

FIGS. 3A-D illustrate example optimization of a photomask pattern in accordance with aspects of the technology. Optimization of a given photomask pattern, as disclosed herein, can include an optimization of that photomask pattern that is unconstrainted by manufacturability constraints. For example, this unconstrained optimization of a photomask pattern can be permitted to yield a resulting photomask pattern having one or more features that are smaller than a minimum feature size associated with a particular semiconductor fabrication process or system. This unconstrained optimization can result in a resulting photomask pattern having a feature that is smaller than a minimum feature size such that if that resulting photomask pattern were used to form a photomask, that photomask may not have that feature, that feature may flake off the photomask, and/or that feature may contaminate other features on the photomask. Such features may not correspond to any feature of a target physical design.

This unconstrained optimization of a photomask pattern may yield a resulting photomask pattern having SRAFs. As noted above, SRAFs of a photomask pattern may sharpen corresponding corners of features of a pattern formed on a wafer using a photomask based on that photomask pattern. Thus, SRAFs can be beneficial in improving correspondence between a target physical design and the pattern formed on a wafer.

FIG. 3A illustrates a photomask pattern 300 following an unconstrained optimization as described herein. By way of example, the photomask pattern 300 has two features 302 and 304. However, the disclosed approaches can be used with photomask patterns having fewer or greater than two features. As a result of the unconstrained optimization, the photomask pattern 300 also includes a void 306 in the feature 302 and an island 308. As used herein, “void” refers to a void within a feature that is smaller than a minimum feature size. As used herein, “island” refers to a feature that is smaller than a minimum feature size.

Following the unconstrained optimization, voids and islands of the resulting photomask pattern may be identified and removed by one or more image filtering and/or imaging smoothing techniques. Non-limiting examples of image filtering and/or imaging smoothing techniques include morphological opening and closing, and other convolutional techniques. Morphological opening and closing includes dilating polygons corresponding to features of a photomask pattern and eroding the dilated polygons with a kernel. Errors caused by removal of voids and islands from a photomask pattern can be repaired.

FIG. 3B illustrates a photomask pattern 310 following identification and removal of the void 306 and the island 308 (illustrated in FIG. 3A) by one or more image filtering and/or imaging smoothing techniques as described herein. The photomask pattern 310 has the features 302 and 304 but without the void 306 and the island 308. A small sub-resolution feature (e.g., SRAF) may move the edge of a contour slightly by, for example, directly moving the edge itself, or adding or removing other sub-resolution features, which may be larger or more distant.

If the unconstrained optimization were performed again using the photomask pattern 310, then the void 306 and the island 308 would reappear. Other voids and islands may be introduced as well. Following removal of voids and islands, a photomask pattern can be optimized in such a way that prevents introduction of other voids and islands. The unconstrained optimization can be considered as a first phase of optimization of one or more approaches disclosed herein. The optimization following removal of voids and islands can be considered as a second phase of optimization of one or more approaches disclosed herein.

By way of example, this second phase of optimization can be based on an objective function and a gradient pattern. As used herein, “objective function” refers to a mathematical function that corresponds to one or metric associated with a target physical design. A photomask pattern can be represented as a grid of pixels. Each pixel can have a corresponding value that is indicative of whether that pixel is turned on (e.g., a value of 1), whether that pixel is turned off (e.g., a value of 0), or a dose for that pixel. For each pixel of the photomask pattern, gradients of an objective function for a target physical design can be determined. These gradients are indicative of whether making a given pixel darker (e.g., turning that pixel on, increasing a dose of that pixel) or making a given pixel lighter (e.g., turning that pixel off, decreasing a dose of that pixel) would improve correspondence of a pattern formed on a wafer using of that photomask pattern to the target physical design. The gradients for an objective function and a photomask pattern can be referred to collectively as a gradient pattern.

In one or more approaches, the objective function can be modified by adjusting weights of one or more pixels of a photomask pattern. By way of example, pixels of a photomask pattern corresponding to one or more features, or portions thereof, of that photomask pattern may be weighted more heavily than one or more other features, or portions thereof, of that photomask pattern. This weighting is applied to the objective function. A goal of this disclosed optimization is to reduce the overall loss (e.g., the difference between the simulated mask patterns and target physical designs), which may be summed for the entire target physical design. If this loss is weighted more heavily in some regions, then the optimization will focus on minimize errors and matching the simulated mask pattern to the target physical design in those regions, sometimes at the expense of other regions in which loss is not as heavily weighted. This weighting enables the optimization to be tailored to focus on regions of interest and identify regions where errors can be tolerated. The modified objective function can be propagated back through the photomask pattern. Gradients of that modified objective function can be determined.

The second phase of optimization of the photomask pattern can include purposeful manipulation of values corresponding to one or more pixels of a gradient pattern for that photomask pattern (e.g., multiplying the gradient pattern with a gradient mask pattern) to prevent this optimization from introducing voids and islands. By way of example, for pixels of the gradient pattern that do not correspond to pixels of the photomask pattern corresponding to boundaries of features of that photomask pattern values of gradients can be set to zero. By way of example, a pixel of a photomask pattern having a non-zero value that is adjacent to another pixel of that photomask pattern having a value of zero corresponds to a boundary of a feature. Such pixels are also referred to herein as boundary pixels.

Setting a value of a given pixel of a gradient pattern to zero causes the corresponding pixel of a photomask pattern to be unaffected by an optimization; in this case, the second phase of optimization. Thus, the second phase of optimization may affect only boundary pixels of a photomask pattern. Because of this purposeful manipulation of the gradient pattern, the second phase of optimization does not, and cannot, introduce new single-pixel or few-pixel features, such as voids or islands.

In some approaches, values of additional pixels of a gradient pattern can be set to zero (e.g., multiplied by zero). By way of example, values of all pixels of a gradient pattern except those that are adjacent to pixels of that gradient pattern corresponding to boundary pixels of a photomask pattern can be set to zero as well. That is, for instance, values of pixels of a gradient pattern that are one or two pixels inward and/or outward relative to those pixels corresponding to boundary pixels of a photomask pattern can be preserved (e.g., multiplied by one). If values of pixels of a gradient pattern that are more than two pixels inward and/or outward relative to those pixels corresponding to boundary pixels of a photomask pattern are preserved, then the optimization may proceed faster because contours can grow or shrink by more than just one pixel in each iteration. Although there is a greater chance that new sub-resolution features may emerge with wider regions around boundaries, but these new sub-resolution features can be periodically deleted.

FIG. 3C illustrates a gradient mask pattern 320 for the photomask mask pattern 310 illustrated by FIG. 3B. As discussed above, values of boundary pixels of a gradient pattern (and, in some embodiments, pixels adjacent to those boundary pixels) are set to one. Values of all other pixels of that gradient pattern are set to zero. Accordingly, the gradient mask pattern 320 includes only boundary pixels 322 corresponding to the feature 302 and boundary pixels 324 corresponding to the feature 304. Values of the boundary pixels 322 and 324 are set to one. Values of pixels corresponding to the feature 302 within the boundary pixels 322 and pixels corresponding to the feature 304 within the boundary pixels 324 are set to zero. The gradient mask pattern 320 is used to perform the second phase of optimization on the photomask pattern 310.

FIG. 3D illustrates an optimized photomask pattern 330 resulting from the second phase of optimization on the photomask pattern 310 illustrated by FIG. 3B using the gradient mask pattern 320 illustrated by FIG. 3C. As discussed above, the gradient mask pattern 320 focuses the second phase of optimization on the boundaries of the features 302 and 304 of the photomask pattern 310. Here, the second phase of optimization adjusts corners (e.g., sharp corners) of the features 302 and 304.

As illustrated by FIG. 3D, the optimized photomask pattern 330 includes outside corners 332, 334, 336, 338 and 340 of the feature 302 being enlarged relative to the photomask pattern 310. That is, the optimized photomask pattern 330 includes additional material being formed at and/or near the outside corners 332, 334, 336, 338 and 340 of the feature 302 relative to the photomask pattern 310. The optimized photomask pattern 330 includes inside corner 342 of the feature 302 being enlarged relative to the photomask pattern 310. That is, the optimized photomask pattern 330 includes less material being formed at and/or near the inside corner 342 of the feature 302 relative to the photomask pattern 310. The optimized photomask pattern 330 includes outside corner 344 of the feature 304 being enlarged relative to the photomask pattern 310. That is, the optimized photomask pattern 330 includes additional material being formed at and/or near the outside corner 344 of the feature 304 relative to the photomask pattern 310.

The optimized photomask pattern 330 can be considered as a purposefully distorted version of the photomask pattern 310. It can be counterintuitive that purposefully distorting a photomask pattern can result in a wafer pattern formed using that distorted version of that photomask pattern has improved correspondence to a target physical design than using the undistorted photomask pattern. This can also be counterintuitive from what an optimization would drive to, finding a photomask pattern that itself has an improved correspondence to a target physical design. This purposeful distortion of a photomask pattern can mitigate and/or compensate for optical diffraction, resist diffusion, and/or other physical effects associated with forming a wafer pattern.

Here, the adjustment (distortion) of the corners of the features 302 and 304 in the optimized photomask pattern 330 results in a wafer pattern formed using the optimized photomask pattern 330 having improved correspondence to the target physical design than a wafer pattern formed using the photomask pattern 310.

In some instances, the second phase of optimization may result in a feature of a photomask pattern being reduced in size to smaller than a minimum feature size. If the optimized photomask pattern includes a feature that has been reduced in size to smaller than a minimum feature size, then that feature can be removed by one or more image filtering and/or imaging smoothing techniques as described herein. However, even if the second phase of optimization reduces the size of an existing feature of a photomask pattern, the second phase of optimization does not introduce (e.g., add) an island or void.

In some instances, the second phase of optimization can be repeated to further improve correspondence of a wafer pattern to a target physical design. By way of example, values of boundary pixels of a gradient pattern corresponding to the optimized photomask pattern 330 can be set to one and values of all other pixels of that gradient pattern can be set to zero. Then, that gradient pattern can be used to further optimize the optimized photomask pattern 330.

### Example Methods

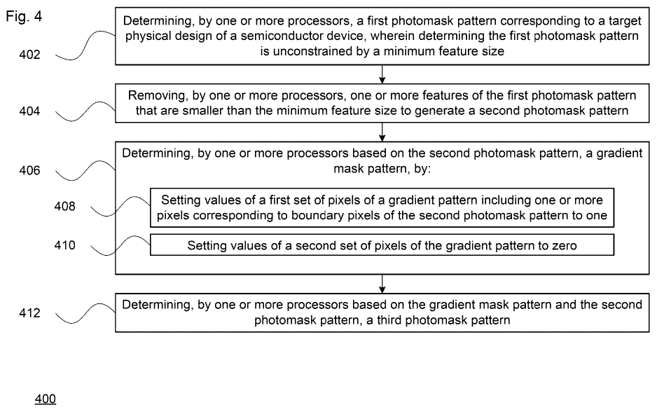

FIG. 4 illustrates an example method 400 in accordance with the above discussion. The method 400 includes, at block 402, determining, by one or more processors, a first photomask pattern corresponding to a target physical design of a semiconductor device, wherein determining the first photomask pattern is unconstrained by a minimum feature size. At block 404, the method 400 includes removing, by one or more processors, one or more features of the first photomask pattern that are smaller than the minimum feature size to generate a second photomask pattern. At block 406, the method 400 includes determining, by one or more processors based on the second photomask pattern, a gradient mask pattern, by, at block 408, setting values of a first set of pixels of a gradient pattern including one or more pixels corresponding to boundary pixels of the second photomask pattern to one, and, at block 410, setting values of a second set of pixels of the gradient pattern to zero. At block 412, the method 400 includes determining, by one or more processors based on the gradient mask pattern and the second photomask pattern, a third photomask pattern.

Although the technology herein has been described with reference to particular embodiments and configurations, it is to be understood that these embodiments and configurations are merely illustrative of the principles and applications of the present technology. It is therefore to be understood that numerous modifications may be made to the illustrative embodiments and configurations, and that other arrangements may be devised without departing from the spirit and scope of the present technology as defined by the appended claims.

1. A method, comprising:
determining, by one or more processors, a first photomask pattern corresponding to a target physical design of a semiconductor device, wherein determining the first photomask pattern is unconstrained by a minimum feature size;
removing, by one or more processors, one or more features of the first photomask pattern that are smaller than the minimum feature size to generate a second photomask pattern;
determining, by one or more processors based on the second photomask pattern, a gradient mask pattern, by:
setting values of a first set of pixels of a gradient pattern including one or more pixels corresponding to boundary pixels of the second photomask pattern to one; and
setting values of a second set of pixels of the gradient pattern to zero; and
determining, by one or more processors based on the gradient mask pattern and the second photomask pattern, a third photomask pattern.

2. The method of claim 1, wherein the first set of pixels further includes one or more pixels of the gradient pattern corresponding to one or more pixels of the second photomask pattern adjacent to the boundary pixels.

3. The method of claim 1, wherein the second set of pixels includes all pixels of the gradient pattern other than the first set of pixels.

4. The method of claim 1, wherein determining the third photomask pattern includes purposefully distorting the second photomask pattern relative to the target physical design.

5. The method of claim 4, wherein purposefully distorting the second photomask pattern includes compensating for at least one of optical diffraction or resist diffusion associated with forming a pattern on a wafer using the third photomask pattern.

6. The method of claim 1, wherein determining the gradient mask pattern further includes identifying the boundary pixels.

7. The method of claim 1, wherein determining the third photomask pattern does not introduce an island or a void.

8. The method of claim 1, further comprising causing the semiconductor device to be fabricated based on the third photomask pattern.

9. A system, comprising:
memory configured to store a target physical design of a semiconductor device to be fabricated; and
one or more processors operatively coupled to the memory, the one or more processors being configured to:
determine a first photomask pattern corresponding to the target physical design, wherein the determination of the first photomask pattern is unconstrained by a minimum feature size;
remove one or more features of the first photomask pattern that are smaller than the minimum feature size to generate a second photomask pattern;
determine, based on the second photomask pattern, a gradient mask pattern, by being configured to:
set values of a first set of pixels of a gradient pattern including one or more pixels corresponding to boundary pixels of the second photomask pattern to one; and
set values of a second set of pixels of the gradient pattern to zero; and
determine, based on the gradient mask pattern and the second photomask pattern, a third photomask pattern.

10. The system of claim 9, wherein the first set of pixels further includes one or more pixels of the gradient pattern corresponding to one or more pixels of the second photomask pattern adjacent to the boundary pixels.

11. The system of claim 9, wherein the second set of pixels includes all pixels of the gradient pattern other than the first set of pixels.

12. The system of claim 9, wherein the one or more processors are further configured to purposefully distort the second photomask pattern relative to the target physical design to determine the third photomask pattern.

13. The system of claim 12, wherein the one or more processors are further configured to purposefully distort the second photomask pattern by being configured to compensate for at least one of optical diffraction or resist diffusion associated with forming a pattern on a wafer using the third photomask pattern.

14. The system of claim 9, wherein the one or more processors are further configured to identify the boundary pixels.

15. The system of claim 9, wherein the one or more processors are further configured to determine the third photomask pattern without introducing an island or a void.

16. The system of claim 9, wherein the one or more processors are further configured to cause the semiconductor device to be fabricated based on the third photomask pattern.
